(19) United States
(12) Patent Application Publication
(10) Pub. No.: US 2013/0005101 A1
(43) Pub. Date: Jan. 3, 2013

(54) METHOD FOR PRODUCING A SEMICONDUCTOR DEVICE INCLUDING A DIELECTRIC LAYER

(75) Inventors: Hans Weber, Bayerisch Gmain (DE); Franz Hirler, Isen (DE); Andreas Peter Meiser, Sauerlach (DE)

(73) Assignee: Infineon Technologies Austria AG, Villach (AT)

(21) Appl. No.: 13/173,872

(22) Filed: Jun. 30, 2011

(51) Int. Cl. H01L 21/336

(52) U.S. Cl. 438/270; 257/E21.41

(57) ABSTRACT

A method for producing a semiconductor device with a dielectric layer includes: providing a semiconductor body with a first trench extending into the semiconductor body, the first trench having a bottom and a sidewall; forming a first dielectric layer on the sidewall in a lower portion of the first trench; forming a first plug in the lower portion of the first trench so as to cover the first dielectric layer, the first plug leaving an upper portion of the sidewall uncovered; forming a sacrificial layer on the sidewall in the upper portion of the first trench; forming a second plug in the upper portion of the first trench; removing the sacrificial layer, so as to form a second trench having sidewalls and a bottom; and forming a second dielectric layer in the second trench and extending to the first dielectric layer.

### TECHNICAL FIELD

Embodiments of the present invention relate to a method for producing a semiconductor device with a dielectric layer, in particular with a vertical and a buried horizontal dielectric layer.

### BACKGROUND

In various integrated circuits a vertical dielectric layer is implemented. A “vertical dielectric layer” is a dielectric layer that extends in a vertical direction of a semiconductor body in which the circuit is integrated. The vertical dielectric layer may be used to dielectrically insulate different semiconductor devices of the circuit. In a new type of MOS transistor, a dielectric layer extends along a drift region of the MOS transistor and dielectrically insulates the drift region from a drift control region, where the drift control region serves to control a conducting channel in the drift region along the dielectric layer.

According to a known method, a vertical dielectric layer can be produced by forming a trench in the semiconductor body, forming the dielectric layer on at least one sidewall of trench and filling the trench with a monocrystalline semiconductor material. However, the dielectric layer may have a poor adhesion to the monocrystalline “filling material” and a huge number of oxide charges may be trapped along the interface between the dielectric layer and the semiconductor material. Thus, the dielectric layer may be removed using an etching technique and may be replaced by another dielectric layer formed by an oxidation step.

An etching technique, however, may be critical in those cases in which there is a horizontal dielectric layer arranged in the semiconductor body that adjoins the vertical dielectric layer. Etching the vertical layer would also partially etch the horizontal layer, which is undesirable.

There is, therefore, a need for an improved method for producing a semiconductor device including a dielectric layer, in particular a vertical dielectric layer.

### SUMMARY

According to an embodiment of a method for producing a semiconductor device with a dielectric layer, the method includes providing a semiconductor body with a first trench extending into the semiconductor body, the first trench having a bottom and a sidewall, forming a first dielectric layer on the sidewall in a lower portion of the first trench, forming a first plug in the lower portion of the first trench so as to cover the second dielectric layer, the first plug leaving an upper portion of the sidewall uncovered, forming a sacrificial layer on the sidewall in the upper portion, and forming a second plug in the upper portion of the first trench. The method further includes removing the sacrificial layer, so as to form a second trench having sidewalls and a bottom, and forming a second dielectric layer in the second trench and extending to the first dielectric layer.

According to another embodiment of a method for producing a semiconductor device with a dielectric layer, the method includes providing a semiconductor body with a first trench extending from a first surface into the semiconductor body. The first trench has a bottom and a sidewall. The method further includes forming a protection layer on the sidewall, forming a sacrificial layer on the sidewall, and forming a semiconductor plug in the first trench. Further, a second trench is formed between the semiconductor body and the semiconductor plug, wherein forming the second trench at least includes removing the sacrificial layer, and a first dielectric layer is formed in the second trench.

Those skilled in the art will recognize additional features and advantages upon reading the following detailed description, and upon viewing the accompanying drawings.

### BRIEF DESCRIPTION OF THE DRAWINGS

Embodiments will now be explained with reference to the drawings. The drawings serve to illustrate the basic principle, so that only aspects necessary for understanding the basic principle are illustrated. The drawings are not to scale. In the drawings the same reference characters denote like features.

FIGS. 1A to 1G illustrate a first embodiment of a method for producing a semiconductor device with a vertical dielectric layer;

FIG. 2 illustrates a horizontal cross sectional view of a semiconductor body according to FIG. 1A according to a first embodiment;

FIG. 3 illustrates a horizontal cross sectional view of a semiconductor body according to FIG. 1A according to a second embodiment;

FIGS. 4A to 4D illustrate an embodiment of a method for producing a dielectric layer on a sidewall in a lower portion of a trench;

FIGS. 5A to 5E illustrate a further embodiment of a method for producing a semiconductor device with a vertical dielectric layer;

FIGS. 6A to 6D illustrate an embodiment of a method for producing a protection layer and a sacrificial layer on a sidewall of a trench;

FIGS. 7A to 7E illustrate a first modification of the methods of FIGS. 4 and 5;

FIGS. 8A to 8E illustrate a second modification of the methods of FIGS. 4 and 5;

FIGS. 9A to 9B illustrate a third modification of the methods of FIGS. 4 and 5;

FIGS. 10A to 10G illustrate a fourth modification of the methods of FIGS. 4 and 5;

FIGS. 11A to 11E illustrate a fifth modification of the methods of FIGS. 4 and 5;

FIGS. 12A to 12E illustrate a further modification of the methods of FIGS. 4 and 5;

FIG. 13 illustrates a vertical cross sectional view of a semiconductor body with a horizontal and a vertical dielectric layer;

FIG. 14 illustrates a horizontal cross sectional view of the semiconductor body of FIG. 12, according to a first embodiment;

FIG. 15 illustrates a horizontal cross sectional view of the semiconductor body of FIG. 12, according to a second embodiment;

FIG. 16 illustrates a first vertical cross sectional view of a MOSFET with a vertical dielectric layer; and

FIG. 17 illustrates a second vertical cross sectional view of a MOSFET with a vertical dielectric layer.

### DETAILED DESCRIPTION

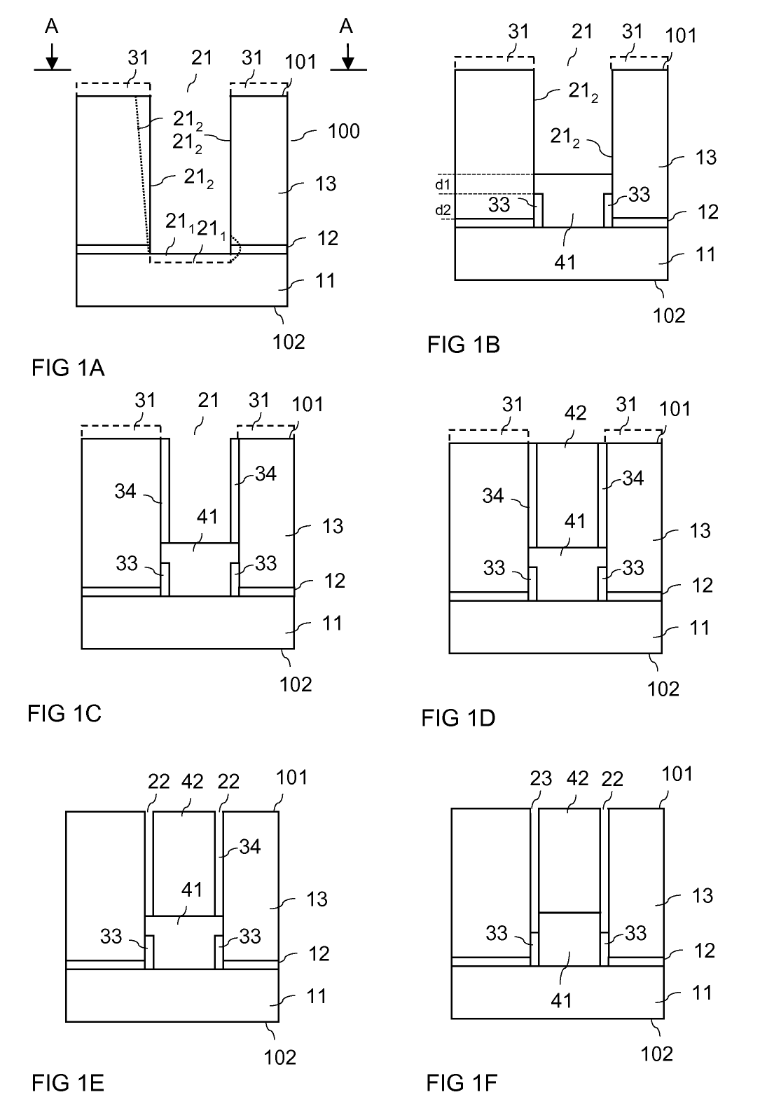

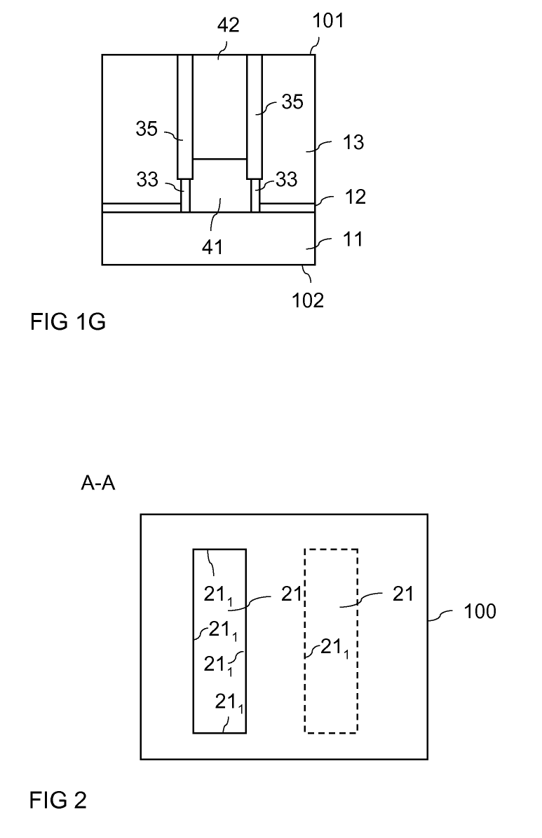

FIGS. 1A to 1G schematically illustrate a first embodiment of a method for producing a semiconductor device that includes a vertical dielectric layer. FIGS. 1A to 1H each show a vertical cross sectional view of a semiconductor body 100 in which the vertical dielectric layer is produced. In these figures only a section of the semiconductor body 100 is illustrated.

Referring to FIG. 1A, the method includes providing a semiconductor body 100 with a first semiconductor layer 11, a second semiconductor layer 13 and a first dielectric layer 12 arranged between the first semiconductor layer 11 and the second semiconductor layer 13. The semiconductor body 100 further includes at least one first trench 21 that, from a first surface 101 of the semiconductor body 100, extends through the second semiconductor layer 13 and the first dielectric layer 12 to the first semiconductor layer 11.

The first trench 21 may extend just down to the first semiconductor layer 11 from the first surface 101, but may also extend into the first semiconductor layer 11 (which is illustrated in dashed lines in FIG. 1A). The first trench 21 has a bottom 21₁ formed by the first semiconductor layer 11, and has at least one sidewall 21₂. The number of sidewalls 21₁ of the trench 21 is dependent on the geometry of the trench 21.

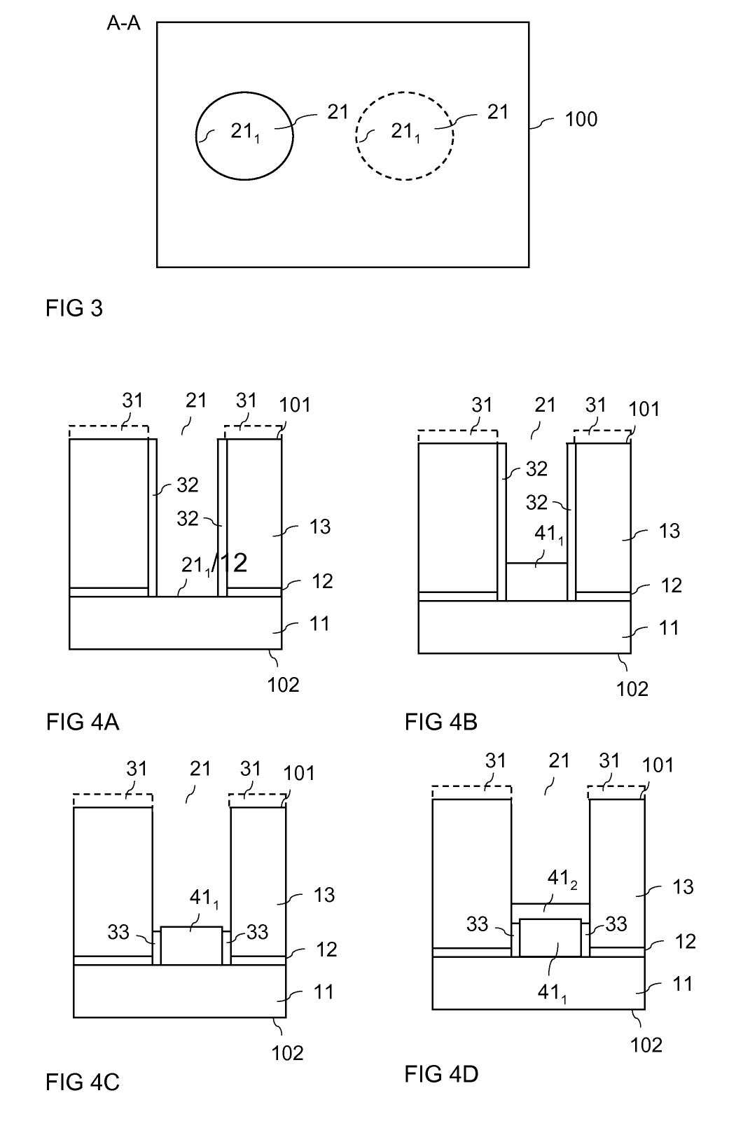

Referring to FIG. 2, which schematically illustrates a horizontal cross sectional view of the semiconductor body 100, the trench 21 may have a widely rectangular geometry. In this case, the trench 21 has four sidewalls 21₁. According to a further embodiment illustrated in FIG. 3, the trench 21 may have an elliptical or circular geometry. In this case the trench 21 has only one sidewall 21₁. It should be noted, that forming the trench 21 with a rectangular or circular geometry is only an example. Any other trench geometry, such as a polygonal geometry, may be implemented as well.

In the following, the term “sidewall” denotes at least one sidewall of a trench. The processing of the sidewall which will be explained in the following can be applied to each sidewall of a trench with several sidewalls, but may also be applied to less sidewalls than the overall number of sidewalls.

According to one embodiment, the first and second semiconductor layers 11, 13 are monocrystalline semiconductor layers. The first dielectric layer 12 includes or is comprised of an oxide, a nitride, a high-k-dielectric, or a composite structure with two or more different dielectric layers.

The semiconductor body 100 according to FIG. 1A is, for example, obtained by providing a semiconductor body 100 with the first and second semiconductor layers 11, 13 and the first dielectric layer 12, and by etching a trench 21 from a first surface 101 through the second semiconductor layer 13 and the first dielectric layer 12 down to or down into the first semiconductor layer 11. Etching the first trench 21 may include using an etch mask 31 applied to the first surface 101. The etch mask 31 is illustrated in dashed lines in FIG. 1A. The etch mask 31 is, for example, a hard mask, in particular an oxide hard mask. The method for etching the first trench 21 may involve two etching steps, a first etching step that etches the second semiconductor layer 13 down to the first dielectric layer 12, and a second etching step that etches through the dielectric layer 12 down to the first semiconductor layer 11. The etching process used for etching the dielectric layer 12 may also slightly etch the semiconductor layers 11, 13, in particular, the first semiconductor layer 11. In this case, the trench 21 extends into the first semiconductor layer 11. According to one embodiment, the etching steps are anisotropic etching steps.

According to a further embodiment, the etching process for etching the second semiconductor layer 13 is an anisotropic process, while the etching process for etching the dielectric layer 12 is an isotropic process. This may result in a structure that is illustrated in dotted lines in the right section of the trench 21, in which the trench 21 widens in the region of the dielectric layer 12. The isotropic process for etching the dielectric layer 12 may also slightly etch the semiconductor layers 11, 13.

As will be apparent from the explanation below, the orientation of the trench sidewall 21₂ defines the orientation of the dielectric layer to be produced in the semiconductor body 100. In the embodiment illustrated in FIG. 1A, the trench sidewall 21₁ extends in a vertical direction of the semiconductor body 100. The vertical direction is a direction perpendicular to the first surface 101 and a second surface 102. The second surface 102 is opposite the first surface 101, where the first surface 101 is formed by the second semiconductor layer 13, and the second surface 102 is formed by the first semiconductor layer 11.

However, forming the trench 21 with a vertical sidewall 21₂ is only an example. According to a further embodiment (illustrated in dotted lines), the trench 21 could also be produced with a beveled sidewall 21₂. A bevel angle, which is an angle between the first surface 101 and the sidewall 21₂ is, for example, in the range of between 60° and 120°, in particular between 80° and 100°. When the bevel angle is below 90°, the trench becomes wider in the direction of the bottom 21₁, and when the bevel angle is above 90°, the trench becomes narrower in the direction of the bottom 21₁.

Referring to FIG. 1A, the first dielectric layer 12 is uncovered at the sidewall 212 Dependent on whether or not the trench 21 extends into the first semiconductor layer 11, the uncovered sections of the first dielectric layer 12 are arranged distant to the bottom 21₁ of the trench 21 or adjoin the bottom 21₁ of the trench 21.

The semiconductor body 100 with the first and second semiconductor layers 11, 13 and the first dielectric layer 12 can be implemented as an Sal substrate. The semiconductor layers 11, 13 may include any conventional semiconductor material, such as silicon (Si), silicon carbide (SiC), gallium arsenide (GaAs), or gallium nitride (GaN).

Referring to FIG. 1B, the method further includes forming a second dielectric layer 33 on the sidewalls 21₂ in a lower portion of the trench 21 so that the second dielectric layer 33 covers the first dielectric layer 12 on the sidewall 21₂. The second dielectric layer 33 can be a conventional dielectric layer, such as, for example, an oxide layer. An embodiment of a method for producing the second dielectric layer 33 will be explained with reference to FIGS. 4A to 4D below.

Further, a first semiconductor plug 41 is formed in the lower portion of the first trench 21 so as to cover the second dielectric layer 33. The first semiconductor plug 41 includes, for example, a monocrystalline semiconductor material. The first semiconductor plug 41 leaves an upper portion of the sidewall 21₂ uncovered and covers the second dielectric layer 33 in a horizontal direction and in a vertical direction. A layer thickness dl of the first semiconductor plug 41 above the second dielectric layer 33 in the direction of the first surface 101 is, for example, in the range between 5 nm and 100 nm, in particular between 20 nm and 50 nm. The second dielectric layer 33 completely covers the first dielectric layer 12 on the sidewall 21₂. The second dielectric layer 33 may overlap the second semiconductor layer 13 in the direction of the first surface 101. According to one embodiment, the overlap d2 is, for example, in the range of between 20 nm and 2 μm.

Referring to FIG. 1C, a sacrificial layer 34 is formed on the sidewall 21₂ of the trench 21 above the first semiconductor plug 41. According to one embodiment, the sacrificial layer 34 extends from the first semiconductor plug 41 to the first surface 101 along the sidewall 21₂. The sacrificial layer 34 is, for example, a dielectric layer, such as an oxide layer. An oxide layer as the sacrificial layer 34 can be produced by performing an oxidation step that oxidizes the sidewall 21₂ and upper parts of the first semiconductor plug 41, wherein the oxide layer is then removed from the semiconductor plug 41. According to a further embodiment, the sacrificial layer 34 is produced by depositing the sacrificial layer on the sidewall 21₂ and on the semiconductor plug 41, and by removing the sacrificial layer from the semiconductor plug 41.

Referring to FIG. 1D, a second semiconductor plug 42 is formed on the first semiconductor plug 41. The second semiconductor plug 42 may completely fill the trench 21. According to one embodiment, the second semiconductor plug 42 is produced using an epitaxial process, in particular a selective epitaxial process, in which a monocrystalline semiconductor material is grown on the first semiconductor plug 41. The first semiconductor plug 41 may be formed by an epitaxial process that grows a semiconductor material on the bottom 21₁ of the trench 21. The two plugs 41, 42 may have identical or similar doping concentrations.

The etch mask 31 that can be used to etch the first trench 21 may remain on the first surface 101 throughout the method steps illustrated in FIGS. 1A to 1D.

Referring to FIG. 1E, the sacrificial layer 34 is removed so as to form a second trench 22 between the second semiconductor layer 13 and the second semiconductor plug 42. The sacrificial layer 34 is, for example, removed by employing an etching process that etches the material of the sacrificial layer 34 selectively relative to the semiconductor material of the first semiconductor layer 13, of the second semiconductor plug 42. The first semiconductor plug 41 acts as an etch stop in the vertical direction and forms the bottom of the second trench 22.

Referring to FIG. 1F, the second trench 22 is then extended down to the second dielectric layer 33 by removing those sections of the first semiconductor plug 41 arranged between the bottom of the second trench 22 and the second dielectric layer 33, so that a third trench 23 is formed that extends down to the second dielectric layer 33. Removing the first semiconductor plug 41 between the bottom of the second trench 22 and the second dielectric layer 33 includes, for example, an anisotropic etching process that anisotropically etches the semiconductor plug 41 down to the second dielectric layer 33. The third trench 23 does not extend down to the first dielectric layer 12 which remains covered by the second dielectric layer 33.

Referring to FIG. 1G a third dielectric layer 35 is produced in the third trench 23, where the third dielectric layer 35 adjoins the second dielectric layer 33, so that the second and third dielectric layers 33, 35 together form a composite vertical dielectric layer that extends from the first dielectric layer 12 to the first surface 101. Forming the third dielectric layer 35 includes, for example, an oxidation step in which sidewalls of the third trench 23 are oxidized. The third dielectric layer 35 is a high quality dielectric layer with good adhesion to the surrounding semiconductor material and with a reduced number of oxide charges trapped along the interface between the third dielectric layer 35 and the surrounding semiconductor material.

In the method illustrated in FIGS. 1E to 1G, producing the third dielectric layer 35 involves a two-step process which includes removing the semiconductor plug in a region between a bottom of the second trench 23 and the second dielectric layer 33, so as to form a third trench 23, and oxidizing sidewalls of the third trench 23. The third trench 23 does not have to extend down to the second dielectric layer 33. It is also possible to oxidize a part of the semiconductor plug 41 down to the second dielectric layer 33. In this case the oxidized section of the semiconductor plug 41 forms a part of the third dielectric layer 35. According to one embodiment, the semiconductor plug 41 between the bottom of the second trench 23 and the second dielectric layer 33 is not removed, but the semiconductor plug 41 is oxidized in the region below between a bottom of the second trench 23 and the second dielectric layer 33 and forms a first part of the third dielectric layer 35. A second part of the third dielectric layer 35 is formed by oxidizing sidewalls of the second trench 22. The oxidation step that oxidizes the semiconductor plug 41 between the bottom of the second trench 22 and the first dielectric layer 12 may be the same oxidation step that forms the third dielectric layer 35 in the second trench 22.

An embodiment of a method for producing the second dielectric layer 33 (see FIG. 1B) in the lower portion of the trench 21 is now explained with reference to FIGS. 4A to 4D. Referring to FIG. 4A, a dielectric layer 32 is produced on the sidewall 21₂ of the trench 21 so as to extend from the bottom 21₁ of the trench 21 to the first surface 101. Forming the dielectric layer 32 includes, for example, an oxidation step that oxidizes the bottom 21₁ and the sidewall 21₂ of the trench 21 or a deposition step in which a dielectric layer is deposited on the bottom 21₁ and the sidewall 21₂, and removing the dielectric layer from the bottom 21₁. Removing the dielectric layer from the bottom 21₁ may include an anisotropic etching process.

Referring to FIGS. 4B and 4C a mask or plug 41₁ is produced on the bottom 21₁ of the trench (see FIG. 4B), and those sections of the dielectric layer 32 that are not covered by the plug 41₁ are removed from the upper portion of the trench 21. Removing the dielectric layer 32 from the upper portion of the trench 21 may include an isotropic etching process that etches the dielectric layer 32 selectively relative to the semiconductor material of the second semiconductor layer 13 and to the material of the plug 41₁. That section of the dielectric layer 32 that is covered by the plug 41₁ and that remains after the etching process forms the second dielectric layer 33. Referring to FIG. 4C, the dielectric layer 32 can be etched down to below an upper surface of the plug 41₁. A height of the plug 41₁, which is the vertical dimension of the plug 41₁, and the duration of the etching process are selected such that the second dielectric layer 33 has a desired height in the vertical direction. The second dielectric layer 33 covers the first dielectric layer 12 on the sidewall 21₁ of the trench. According to one embodiment, a height, which is the vertical dimension, of the second dielectric layer 33 is, in the range of between 0.1% and 20% of the depths of the trench 21. The “depth” of the trench is the vertical dimension of the trench 21.

In the embodiment illustrated in FIGS. 4A to 4D, the plug 41₁ forms a first section of the first semiconductor plug 41 (see FIG. 1C). In this case, the plug 41₁ can be produced by employing an epitaxial process, in particular a selective epitaxial process in which the plug 41₁ is epitaxially grown on the bottom 21₁ of the trench 21. In this case, the semiconductor plug 41 is completed by growing or depositing a further layer 41₂ on the semiconductor plug 41₁. The further layer 41₂ may be an epitaxially grown semiconductor layer or any other layer that may act as an etch stop in the etching process that etches the sacrificial 34 layer, such as, e.g., a nitride layer, an amorphous silicon layer, or a composite layer with, e.g., a carbon layer and a thin nitride or a thin silicon layer. The second layer 41₂ covers the second dielectric layer 33 in the direction of the first surface 101. The second epitaxial layer 41₂ adjoins a second semiconductor layer in a lateral or horizontal direction. A seam line may occur close to the second semiconductor layer 13 and extend in a vertical direction when the second plug 41₂ is an epitaxial layer. However, this seam line or other crystal defects are in an area that is removed when forming the third trench 23 (see FIG. 1F).

According to a further embodiment (not shown), the plug 41₁ is removed after the method steps illustrated in FIG. 4C, and the first semiconductor plug 41 (see FIG. 1C) is grown on the bottom 21₁ of the trench 21 after removing the spacer. In this case, the plug 41₁ is not necessarily a monocrystalline semiconductor material, but can be any material against which the dielectric layer 32 can be selectively etched, such as, e.g., silicon nitride (Si₃N₄) or carbon (C).

The method explained before—like the method explained below—is not restricted to produce a vertical dielectric layer in a semiconductor body that includes a buried horizontal dielectric layer, such as dielectric layer 12. The method could also be used to produce a vertical dielectric layer in a semiconductor body without the horizontal dielectric layer.

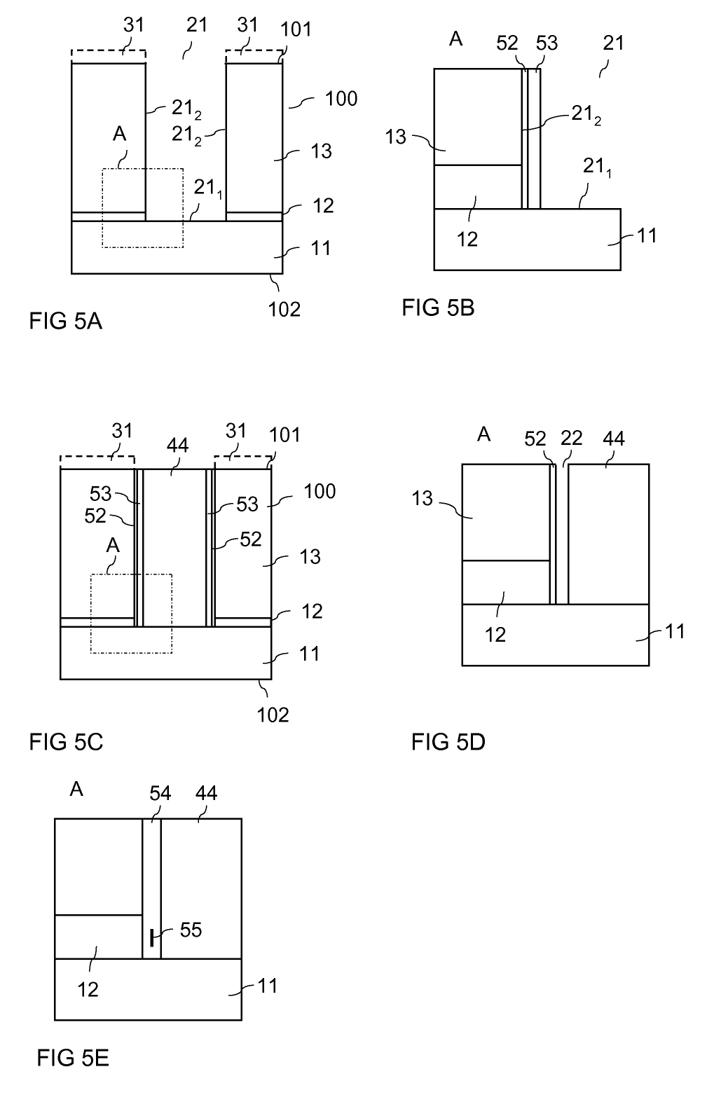

A further embodiment of a method for producing a semiconductor device with a vertical dielectric layer is explained with reference to FIGS. 5A to 5E. Like the method explained before, this method includes providing a semiconductor body 100 with a first semiconductor layer 11, a second semiconductor layer 13 and a first dielectric layer 12 arranged between the first and second semiconductor layers 11, 13. The semiconductor body 100 further includes a trench 21 extending from a first surface 101 through the second semiconductor layer 13 and the first dielectric layer 12 to or into the first semiconductor layer 11. Everything which has been explained concerning the semiconductor body 100 with reference to FIGS. 1A, 2 and 3 applies to the semiconductor body 100 illustrated in FIG. 5A accordingly.

In the following, figures that are additionally labeled with an “A” show a detail of the semiconductor body 100 in a section that is illustrated in dash-dotted lines in FIG. 5A. This section includes a part of the bottom 21₁ and of the sidewall 21₂ of the first trench 21 and of the first dielectric layer 12.

Referring to FIG. 5B a protection layer 52 and a sacrificial layer 53 are formed on the sidewall 21₂, wherein the sacrificial layer 53 covers the protection layer 52. The protection layer 52 covers the first dielectric layer 12 on the sidewall 21₂ and may extend from the bottom 21₁ of the trench 21 to the first surface 101. In this case, the protection layer 52 is arranged between the second semiconductor layer 13 at the sidewall 21₂. According to a further embodiment explained below, the protection layer 52 covers the first dielectric layer 12, but does not extend to the first surface 101. In this case, the sacrificial layer 53 adjoins the second semiconductor layer 13 in sections of the sidewall 21₂ in particular in upper sections of the sidewall 21₂. According to one embodiment, the sacrificial layer 53 extends to the first surface 101 of the semiconductor body 100.

Referring to FIG. 5C, a semiconductor plug 44 is produced in the trench 21. According to one embodiment, the semiconductor plug 44 completely fills the trench 21 and extends to the first surface 101. Referring to FIG. 5D a second trench 22 is formed that extends from the first surface 101 into the semiconductor body 100. In the embodiment illustrated in FIG. 5D, forming the second trench 22 only includes removing the sacrificial layer 53.

Semiconductor plugs filling the trenches, such as plug 41, 42 in FIG. 1G and plug 44 in FIG. 5C, do not have to include the same material as the second semiconductor layer 13. The second semiconductor layer 13 may include a first semiconductor material, while the plug may include a second material. Further, the first semiconductor layer 11 can be different from the second layer 13 and/or the plugs 41, 42 (in FIG. 1G) 44 (in FIG. 5C) in terms of their semiconductor material. Suitable semiconductor materials for implementing the first and second semiconductor layers 11, 13 and the plug 41, 42; 44 are, e.g., silicon (Si) and silicon carbide (SiC). According to one embodiment, the first semiconductor layer 11 includes SiC, while at least one of the second semiconductor layer 13 and the plug includes Si.

Referring to FIG. 5E a second dielectric layer 54 is formed in the second trench 22. Forming the second dielectric layer 54 includes an oxidation step that oxidizes at least the protection layer 52 and the semiconductor plug 44 along sidewalls of the second trench 22. Through the oxidation step, the protection layer 52 is “converted” into a part of the second dielectric layer 54. The protection layer 52 is, for example, a semiconductor layer, such as an amorphous or a polycrystalline semiconductor layer. The material of the semiconductor protection layer 52 may be identical to the material of the second semiconductor layer 13 and the semiconductor plug 44.

In the oxidation step that forms the second dielectric layer 54 also regions of the second semiconductor layer 13 can be oxidized. In those regions of the second trench 22 in which the protection layer 52 covers the first dielectric layer 12, only the protection layer 52 and the semiconductor plug 54 can be “consumed” to form the second dielectric layer 54, but there is no part of the second semiconductor layer 13 in this region that may be “consumed”. Thus, a void 55 may be formed in the second dielectric layer 54 in the region of the first dielectric layer 12. The presence of such void 55 may, however, be tolerated in numerous applications in which the structure according to FIG. 5E with the horizontal first dielectric layer 12 and the vertical second dielectric layer 54 may be employed.

According to a further embodiment, forming the second trench 22 does not only include removing the sacrificial layer 53 but also includes removing the protection layer 52. In this case, sidewalls of the second trench 22 are formed by the second semiconductor layer 13 and forming the second dielectric layer 54 includes oxidizing sidewalls of the second trench 22. Removing the protection layer 52 may include a process that removes the protection layer 52 selectively relative to the first dielectric layer 12.

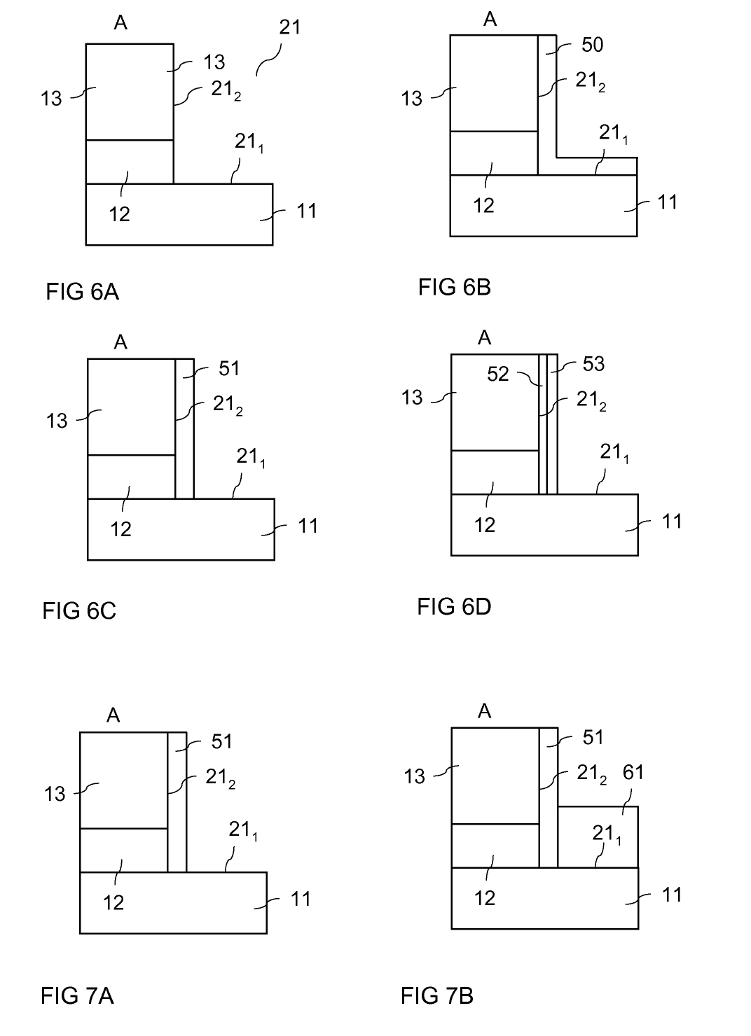

An embodiment of a method for forming the protection layer 52 and the sacrificial layer 53 is now explained with reference to FIGS. 6A to 6D, in which schematically horizontal cross sectional views of detail “A” of the semiconductor body 100 are illustrated.

FIG. 6A shows the semiconductor body with the first and second semiconductor layers 11, 13, the first dielectric layer 12 and the first trench 21. Referring to FIG. 6C a protection and sacrificial layer 51 is formed on the sidewall 21₂. Referring to FIG. 6B, forming the protection and sacrificial layer 51 may include forming a protection and sacrificial layer 50 on the bottom 21₁ and the sidewall 21₂ of the trench 21, and by removing the protection and sacrificial layer 50 from the bottom 21₁. Removing the protection and sacrificial layer 50 from the bottom 21₁ of the trench 21 may include an anisotropic etching process. The protection and sacrificial layer 51 is, for example, a semiconductor layer, such as an amorphous or polycrystalline semiconductor layer of the same material as the protection layer 52 (see FIG. 5D).

In the method explained with reference to FIGS. 6B to 6D, an oxidation step is performed after the protection and sacrificial layer 50 has been removed from the bottom 21₁ of the trench. However, this is only an example. It is also possible to already perform the oxidation step after the protection and sacrificial layer 50 has been formed. In this case, the protection layer 52 and the sacrificial layer 53 are also formed on the bottom 21₁ of the trench 21. The sacrificial layer 53 on the bottom 21₁ of the trench 21 is then removed using, e.g., an anisotropic etching process. The protection layer 51 on the bottom 21₁ of the trench 21 may also be removed. According to one embodiment, the protection and sacrificial layer 50 and, therefore, the protection layer 52 includes a monocrystalline semiconductor material of the same type as the first layer and/or plug 44. In this case, the protection layer 52 may remain on the bottom 21₁ of the trench 21.

Referring to FIG. 6D surface regions of the protection and sacrificial layer 51 are converted into the sacrificial layer 53, while sections of the protection and sacrificial layer 51 which adjoin the first dielectric layer 12 and the second semiconductor layer 13 remain unchanged and form the protection layer 52. Forming the sacrificial layer 53 includes an oxidation process that oxidizes surface regions of the protection and sacrificial layer 51. This oxidation process may also oxidize sections of the first semiconductor layer 11 at the bottom 21₁ of the trench 21. These oxidized bottom sections may then be removed using, for example, an anisotropic etching process before forming the plug 44 (see FIG. 5C).

According to a further embodiment (not shown), the protection layer 52 and then the sacrificial layer 53 are formed. The protection layer 52 is, e.g., a carbon layer, a polycrystalline semiconductor layer, such as a polysilicon layer, or an amorphous semiconductor layer, such as an amorphous silicon layer, while the sacrificial layer 53 is, e.g., a deposited semiconductor-oxide layer (such as TEOS), a nitride layer, or a metal-oxide layer, such as an aluminum-oxide (Al₂O₃) layer.

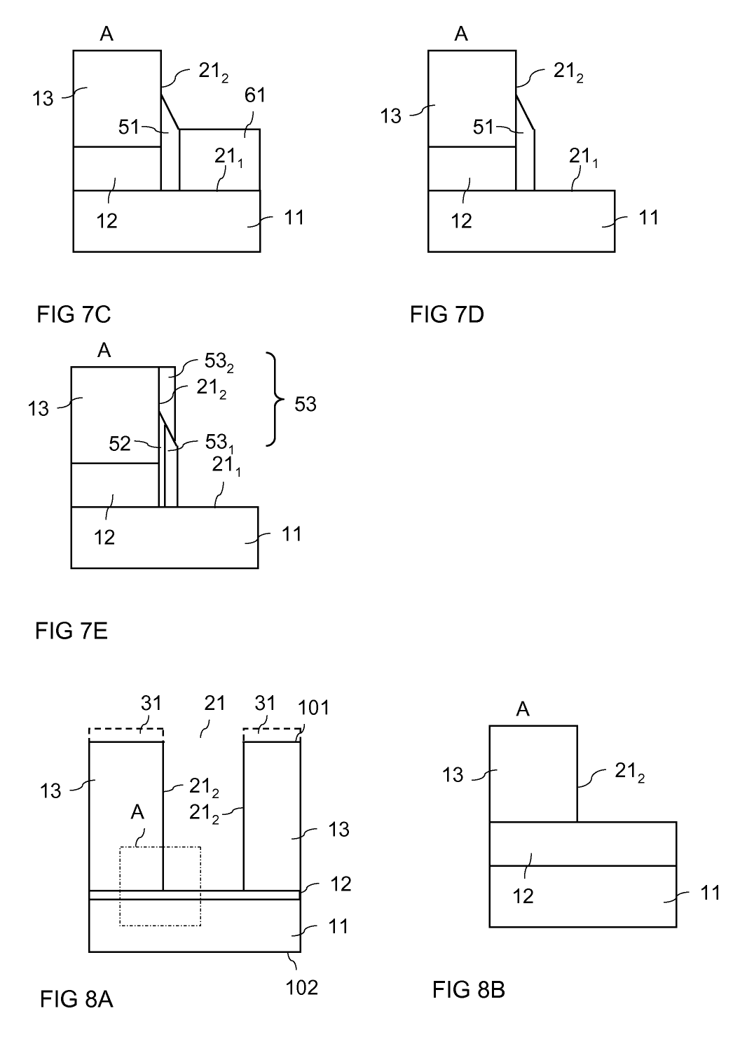

Referring to the explanation provided above, the protection layer 52 may extend along the sidewall 21₂ from the first dielectric layer 12 to the first surface 101 of the semiconductor body. However, this is only an example. Referring to further method steps illustrated in FIGS. 7A to 7D the protection layer can be produced such that it basically covers the first dielectric layer 12 on the sidewall 21₁, but does not extend to the first surface 101. In this case, the sacrificial layer 53 covers the protection layer but also covers (adjoins) sections of the sidewall 21₂.

Referring to FIG. 7A, the protection and sacrificial layer 51 is formed on the sidewall 21₂. The method steps previously explained with reference to FIGS. 6B and 6C can be used to form the protection and sacrificial layer 51 on the sidewall 21₂. Referring to FIGS. 7B to 7D the protection and sacrificial layer 51 is then removed from the sidewall 21₂ in an upper portion of the trench 21. Removing the protection and sacrificial layer 21 may include producing a plug 61 on the bottom 21₁ of the trench 21 (see FIG. 7B), and etching the protection and sacrificial layer 51 on the sidewall 21₂ in upper portions of the trench 21, wherein those sections of the protection and sacrificial layer 51 covered by the plug 61 are protected from being etched (see FIG. 7C). Referring to FIG. 7D, the plug 61 is then removed. Removing the plug 61 may include an etching process that etches the material of the plug 61 selectively relative to the material of the protection and sacrificial layer 51 and the semiconductor material of the first and second semiconductor layers 11, 13. The plug 61 includes, for example, a deposited oxide, such as a HDP (high density plasma) oxide, carbon, or a photo resist.

Referring to FIG. 7E, the protection layer 52 and the sacrificial layer 53 are formed. Forming the sacrificial layer 53 includes an oxidation step that partially oxidizes the protection and sacrificial layer 51 and that oxidizes surface regions of the second semiconductor layer 13 that are uncovered at the sidewall 21₁. Thus, the sacrificial layer 53 includes two sections, a first section 53₁ resulting from oxidizing the protection and sacrificial layer 51 (see FIG. 7D), and a second section resulting from oxidizing the second semiconductor layer 13 at the sidewall 21₂. Like in the method explained with reference to FIGS. 6A to 6D it is also possible to first form the protection layer 52 and to the deposit the sacrificial layer 53 on the protection layer 52.

The further method steps, which include forming the semiconductor plug 54, removing the sacrificial layer 53 and forming the second dielectric layer 54 correspond to the method steps illustrated with reference to FIGS. 5C to 5E.

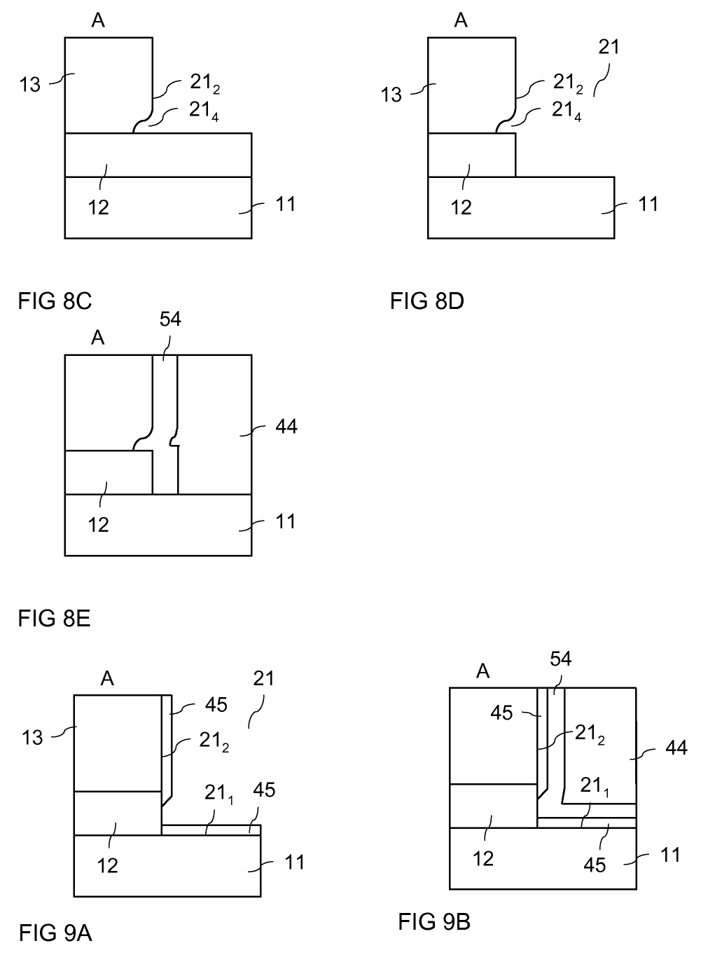

FIGS. 8A to 8E illustrate a modification of the methods explained with reference to FIGS. 5 to 7. Referring to FIGS. 8A and 8B, in this method, the first trench 21 is first produced to only extend to the first dielectric layer 12. Referring to FIG. 8C, an etching process is performed that etches the second semiconductor layer 13 at the bottom of the first trench 21 so as to remove material of the second semiconductor layer 13 in the region of the bottom of the first trench 21.

Referring to FIG. 8D, the first trench 21 is then etched down to the first semiconductor layer 11 or into the first semiconductor layer 11. Referring to FIG. 8E, the semiconductor plug 44 and the second dielectric layer 54 are then formed. Each of the methods explained before with reference to FIGS. 5 to 7 may be used to produce the semiconductor plug 44 and the second dielectric layer 54.

FIGS. 9A to 9B illustrate a further modification of the methods explained before with reference to FIGS. 5 to 7. Referring to FIG. 9A, in this method a semiconductor layer 45 is produced on the bottom 21₁ and the sidewall 21₂ of the trench 21 such that the first dielectric layer 12 is at least partially uncovered at the sidewall 21₂. The semiconductor layer 45 is, for example, formed by employing a selective epitaxial growth process. In this process semiconductor material grows on the first semiconductor layer 11, on the bottom 21₁ of the trench 21, and on the second semiconductor layer 13 on the sidewall 21₂ but does not grow on the first dielectric layer 12. Nevertheless, due to epitaxial overgrowth the semiconductor layer 45 may partially overlap the first dielectric layer 12. After having produced the semiconductor layer 45, the semiconductor plug 44 and the second dielectric layer 54 are produced in correspondence with one of the methods explained with reference to FIGS. 5 to 7. The result is illustrated in FIG. 9B.

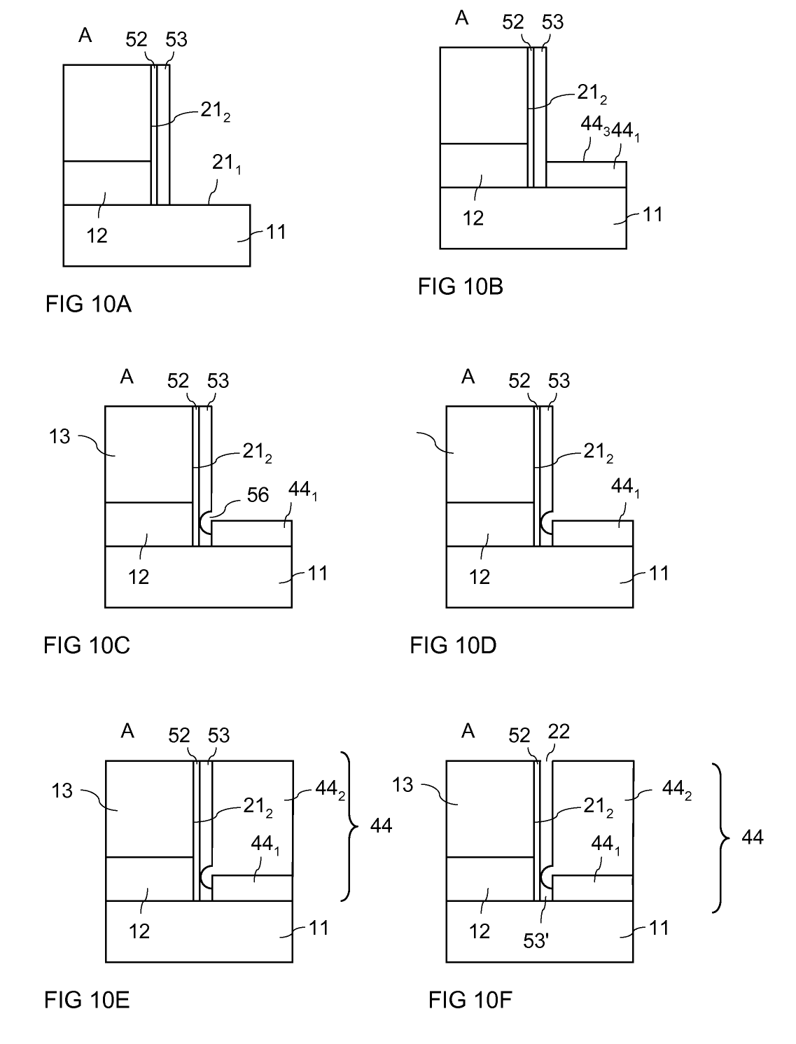

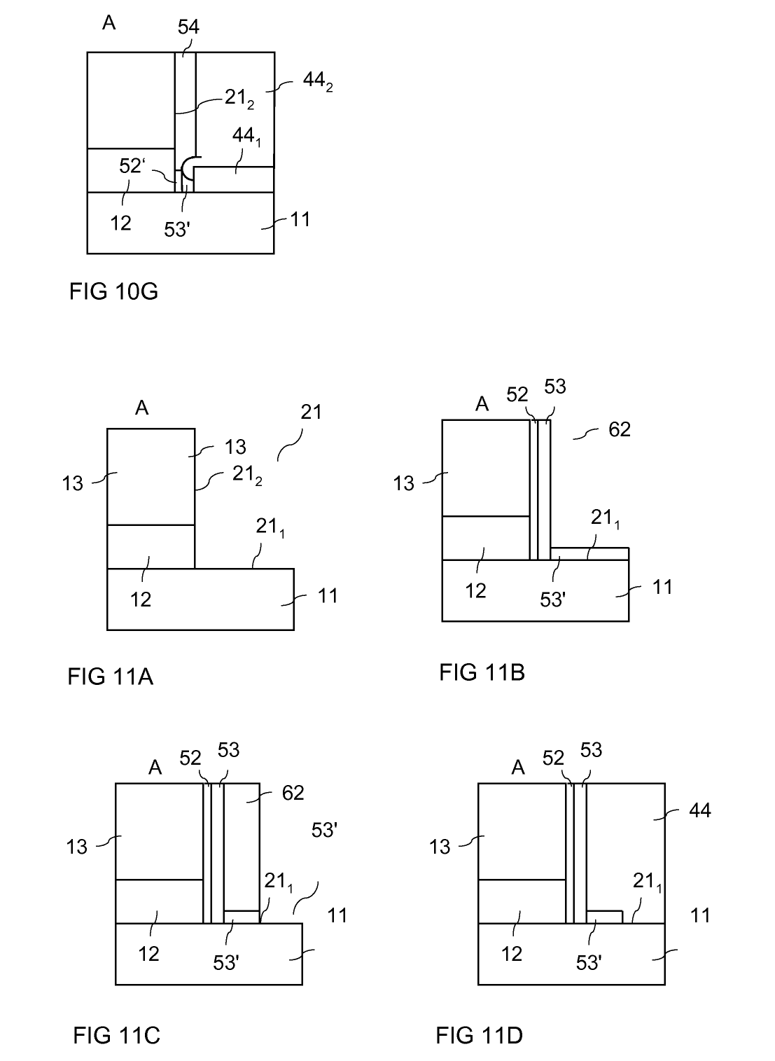

FIGS. 10A to 10G illustrate a further modification of the method according to FIGS. 5 to 7. In this method, after having formed the protection layer 52 and the sacrificial layer 53 on the sidewall 21₂ (see FIG. 10A), the sacrificial layer 53 is partially removed in the region of the first dielectric layer 12, as illustrated in FIG. 10C. Referring to FIG. 10B, partially removing the sacrificial layer 53 in the region of the first dielectric layer 12 includes forming a semiconductor layer 44₁ on the bottom 21₁ of the trench 21. The semiconductor layer 44₁ can be produced by employing a selective epitaxial growth process. Using the semiconductor layer 44₁, the sacrificial layer 53 can be partially removed, so as to form a notch 56 in the sacrificial layer 53 in the region of a surface 44₃ of the semiconductor layer 44₁. Producing the notch 56 may include a temperature process in a hydrogen atmosphere. Assume that the semiconductor layer 44₁ is a silicon layer and that the sacrificial layer 53 is a silicon dioxide (SiO₂) layer. The temperature process in the hydrogen atmosphere then causes silicon atoms from the semiconductor layer 44₁ to accumulate at the sacrificial layer 53 close to the surface 44₃ of the semiconductor layer 44₁. The accumulated silicon atoms react with the silicon dioxide molecules so that volatile silicon oxide (SiO) is formed, i.e. Si+SiO₂->2SiO.

According to one embodiment, the duration of the temperature process is selected such that the notch 56 produced in the sacrificial layer 53 extends to the protection layer 52.

Referring to FIG. 10E, the semiconductor plug 44 is formed in next method steps. The semiconductor layer 44₁ can form a first section of the semiconductor plug 44. In this case, a second section 44₂ of the semiconductor plug 44 is formed on the first section 44₁ by, for example, a selective epitaxial growth process. According to another embodiment, the semiconductor layer 44₁ is removed after the notch 56 in the sacrificial layer 53 has been formed, and the semiconductor plug 44 is formed by epitaxially growing the semiconductor material on the bottom 21₁ of the trench 21.

When the semiconductor plug 44 is formed, the notch 56 in the sacrificial layer 53 is also filled with a semiconductor material. This semiconductor material filling the notch 56 forms a “nose” of the semiconductor plug 44. When the notch 56 is produced to extend to the protection layer 52, this nose of the semiconductor plug 44 in a lateral direction extends to the protection layer 52.

Referring to FIG. 10F, the second trench 22 is formed in next method steps by removing the sacrificial layer 53. The nose of the semiconductor plug 44, however, prevents the second trench 22 from being etched down to the first semiconductor layer 11, so that a section 53′ of the sacrificial layer 53 remains between the nose of the semiconductor plug 44 and the first semiconductor layer 11.

Referring to FIG. 10G, the second dielectric layer 54 is formed by employing the oxidation process. At the end of this process a section 52′ of the protection layer 52 may remain between the nose of the plug 54 and the first semiconductor layer 11.

In the method explained with reference to FIGS. 10A to 10G, the protection layer 51 may extend from the bottom 21₁ of trench 21 to the first surface 101. However, as explained with reference to FIGS. 7A to 7E, it is also possible to produce the protection layer 51 such that it essentially only covers the first dielectric layer 12 on the sidewall 21₂ before the method steps illustrated in FIGS. 10A to 10G are carried out.

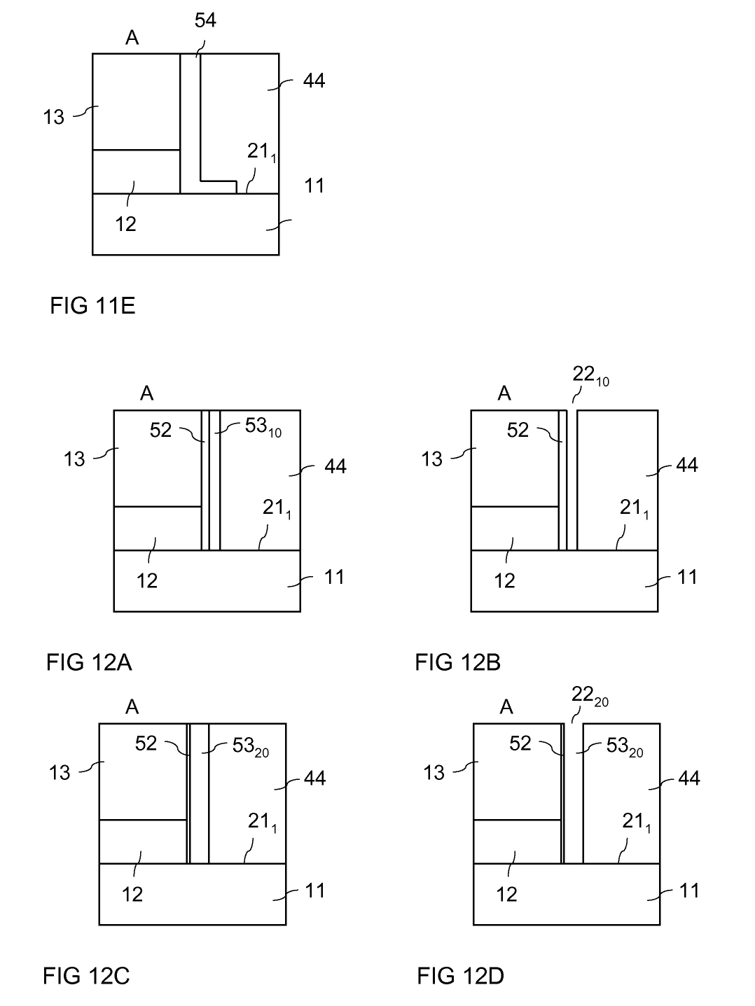

Referring to FIGS. 11A to 11E, the method explained with reference to FIGS. 5 to 7 can also be modified so that the second dielectric layer 54 is not only produced along the sidewall 21₂ of the first trench 21, but also partially covers the trench bottom 21₁.

In the method of FIGS. 11A to 11E the sacrificial layer 53 is formed by an oxidation process that oxidizes the protection and sacrificial layer 50 (not shown in FIGS. 11A to 11C) formed on the sidewall 21₂. The oxidation process also forms an oxide layer 53′ on the trench bottom 21₁, as illustrated in FIG. 11B.

A spacer 62 is formed on the protection and sacrificial layer 50 along the sidewall 21₂. The spacer 62 protects a part 50₁ of the protection and sacrificial layer on the bottom 21₁ of the trench 21 during the method steps that remove the protection and sacrificial layer from the trench bottom 21₁. Removing the protection and sacrificial layer 50 from the bottom 21₁ of the trench 21 has been explained with reference to FIGS. 6B and 6C above.

In further method steps, the result of which is illustrated in FIG. 11C, a spacer 62 is formed on the protection and sacrificial layer 50 along the sidewall 21₂. This spacer 62 protects a part of the oxide layer 53′ on the trench bottom 21₁. The spacer 62 is used to etch the oxide layer on the trench bottom 21₁, so that the part of the oxide layer 53′ protected by the spacer remains after the etching process.

In next method steps which are illustrated in FIGS. 11D and 11E, the semiconductor plug 44 (see FIG. 11D), and the second dielectric layer 54 are formed. By virtue of an L-shape of the structure with the sacrificial layer 53 and the remaining oxide layer 53′ on the trench bottom 21₁, the second dielectric layer 54 also has an L-shape in this embodiment. In the method according to FIGS. 11A to 11D, the protection and sacrificial layer 50 may be an amorphous, a polycrystalline, or a monocrystalline layer.

Alternatively, in the method of FIGS. 11A to 11C, the protection and sacrificial layer 50 is formed on the bottom 21₁ and on the sidewalls 21₂ of the trench 21, and an oxidation step for forming the sacrificial layer 53 is performed without removing the protection and sacrificial layer 50 from the trench bottom 21₁. In this case, the protection layer 52 and the sacrificial layer 53 are formed on the bottom 21₁ and on the sidewall 21₂ of the trench 21, where the sacrificial layer 53 is removed from the trench bottom 21₂ using the spacer 62, while the protection layer 52 remains on the trench bottom 21₁. The remaining sacrificial layer 53 has an L-shape in this case, resulting in an L-shaped second dielectric layer 54. In this embodiment (that is not illustrated) the sacrificial and protection layer 50 and, therefore, the protection layer 52, that remains on the trench bottom 21₂, is, in particular, a monocrystalline layer.

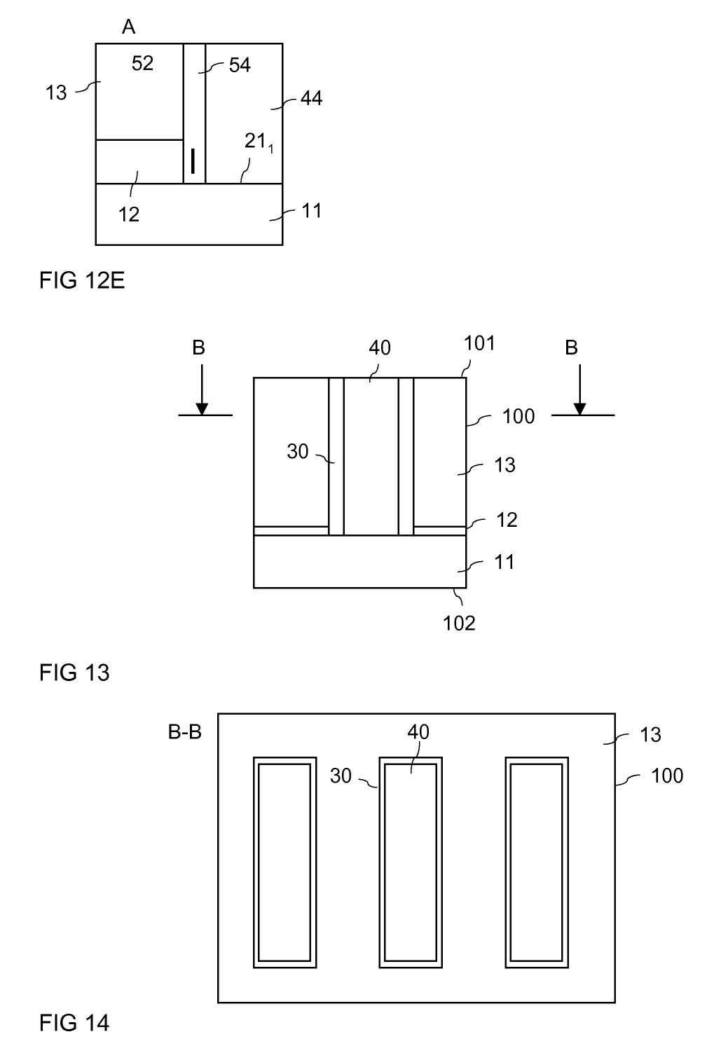

In the methods explained with reference to FIGS. 5 to 11 before, one sacrificial layer 53 is formed before the second semiconductor plug 44 is formed, and the sacrificial layer 53 is removed after the semiconductor plug 44 has been formed. FIGS. 12A to 12E illustrate a method, in which the sacrificial layer is formed in two steps.

Referring to FIG. 12A a first sacrificial layer 53₁₀ is formed before the semiconductor plug 44 is formed. Forming the first sacrificial layer 53₁₀ may correspond to forming the sacrificial layer 53 as explained with reference to FIGS. 5 to 7. Referring to FIG. 12B, the first sacrificial layer 53₁₀ is removed after the semiconductor plug 44 has been formed. Removing the first sacrificial layer 53₁₀ results in a trench 22₁₀.

Referring to FIG. 12C a second sacrificial layer 53₂₀ is formed in this trench 22₁₀. Forming the second sacrificial layer 23₂₀ may include an oxidation process that oxidizes a surface of the semiconductor plug 44 and that further oxidizes the protection layer 52. However, the protection layer 52 is not completely oxidized at this step. In the method illustrated in FIG. 12C, the second sacrificial layer 53₂₀ completely fills the trench 22₁₀. However, this is only an example. According to a further embodiment, the second sacrificial layer 53₂₀ only covers sidewalls of the trench 22₁₀.

Referring to FIG. 12D the second sacrificial layer 53₂₀ is removed, so as to form a second trench 22₂₀ in which the second dielectric layer 54 is formed, as illustrated in FIG. 12E.

The method steps for removing the first sacrificial layer 53₁₀ and for removing the second sacrificial layer 53₂₀ may correspond to the method steps for removing the sacrificial layer 53 explained with reference to FIGS. 5 to 7.

In the method according to FIGS. 12A to 12G, instead of one sacrificial layer, two sacrificial layers are formed, namely a first sacrificial layer 53₁₀ before forming the semiconductor plug 44, and a second sacrificial layer 53₂₀ after forming the semiconductor plug 44. In this method, forming the second sacrificial layer 53₂₀ is part of forming the second trench, in which the second dielectric layer 54 is formed, and serves to widen the second trench in order to produce a thicker second dielectric layer. Thus, in the method of FIG. 12A to 12G, forming the second trench 22₂₀, in which the second dielectric layer 54 is formed, does not only include removing the first sacrificial layer 53₁₀, but includes removing the first sacrificial layer 53₁₀, performing a further oxidation step, so as to form the second sacrificial layer 53₂₀, and to remove this further sacrificial layer 53₂₀.

With the methods explained before, a semiconductor body 100 can be formed that, referring to FIG. 13, essentially includes a first semiconductor layer 11, a semiconductor plug 40 adjoining the first semiconductor layer 11 and dielectrically insulated in a lateral direction from a second semiconductor layer 13 by a dielectric layer 30. A first dielectric/insulating layer 12 is arranged between the first and second semiconductor layers 11, 13. In FIG. 13, semiconductor plug 40 represents one of semiconductor plugs 41, 42 and 44 respectively, explained before. The dielectric layer 30 in FIG. 13 represents one of the vertical dielectric structures extending from the first surface 101 to the first semiconductor layer 11 explained before. According to one embodiment, a plurality of semiconductor plugs 40 are produced in the semiconductor body 100.

Referring to FIG. 14, which illustrates a horizontal cross sectional view of the structure illustrated in FIGS. 13 in a horizontal section plane B-B, the semiconductor plugs 40 can be produced to be completely surrounded by dielectric layers 30 in the horizontal direction, so that the second semiconductor layer 13 surrounds the plugs 40.

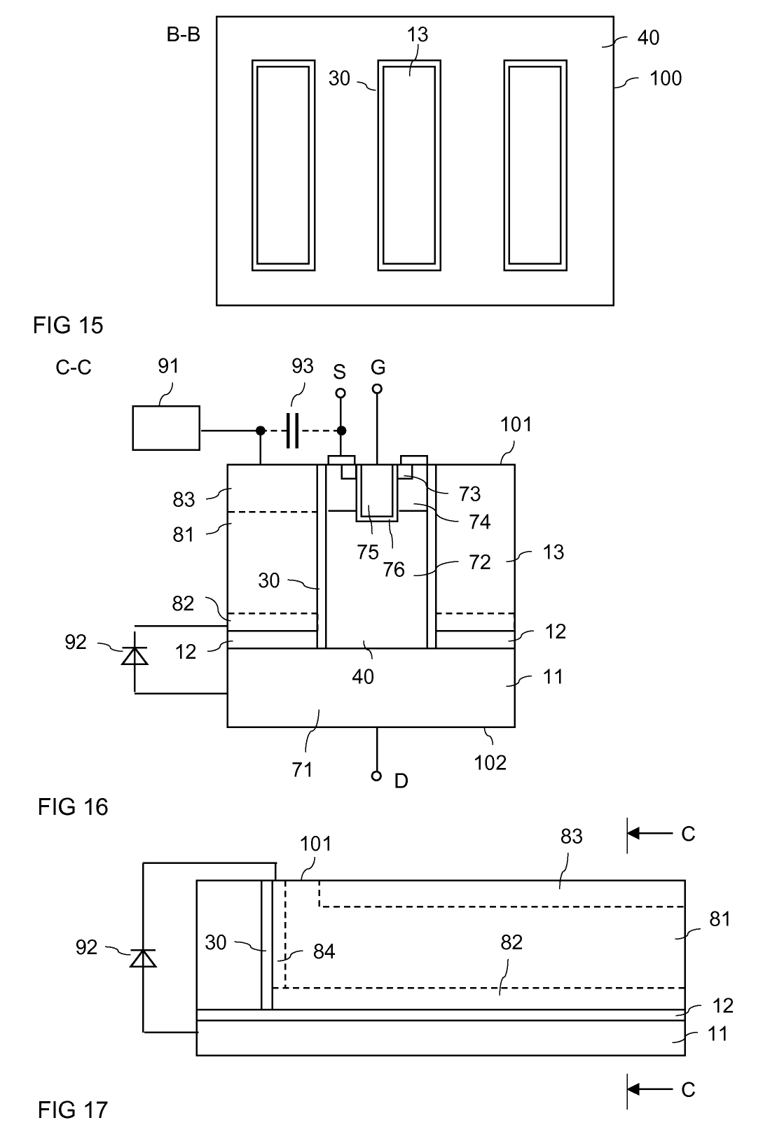

Referring to FIG. 15, which illustrates a further embodiment, the dielectric layer 30 can be produced to completely surround sections of the second semiconductor layer 13, so that the plug 40 surrounds these sections of the second semiconductor layer 13. A structure as illustrated in FIG. 14 can be obtained by producing the first trench 21 with a rectangular, circular or polygonal shape. The structure of FIG. 15 can be obtained when producing the first trench 21 with a grid-like shape.

Based on the structures illustrated in FIGS. 13-15 a MOSFET can be implemented. A vertical cross sectional view of an embodiment of this MOSFET is illustrated in FIG. 16. In this MOSFET, the first semiconductor layer 11 forms a drain region 71 of the MOSFET. The drain region 71 is electrically connected to a drain terminal D that is only schematically illustrated in FIG. 16. In an n-type MOSFET, the drain region 71 is n-doped in a p-type MOSFET the drain region 71 is p-doped. The doping concentration of the drain region 71 corresponds to the doping concentration of the first semiconductor layer 11 which is, for example, in the range of between 5*10¹⁷ cm⁻³ and 10²¹ cm⁻³.

The MOSFET further includes a drift region 72, a source region 73 and a body region 74 arranged between the source region 73 and the drift region 72. The drift region 72, the source region 73 and the body region 74 are formed in the semiconductor plug 40. The MOSFET further includes a gate electrode 75 which extends from the source region 73 through the body region 74 to the drift region 72 and which is dielectrically insulated from these semiconductor regions 72, 73, 74 by a gate dielectric 76. In the embodiment illustrated in FIG. 16, the gate electrode 75 is a trench electrode that is arranged in a trench in the semiconductor plug 40. However, this is only an example. The gate electrode 75 could also be implemented as a planar electrode above the surface 101 of the semiconductor body 100. According to one embodiment, the doping concentration of the drift region 72 corresponds to the basic doping concentration of the semiconductor plug 40. The doping concentration of the semiconductor plug 40 is adjusted during the epitaxial growth process, in which the semiconductor plug 40 is formed. The doping concentration of the drift region 72 is, for example, in the range of between 10¹² cm⁻³ and 10¹⁵ cm⁻³.

The body region 74 and the source region 73 can be produced in a conventional manner by implantation and/or diffusion processes. The gate electrode 75 and the gate dielectric 76 can also be produced in a conventional manner by etching processes, gate dielectric forming processes and gate electrode forming processes. In an n-type MOSFET, the source region 73 is n-doped, while in a p-type MOSFET, the source region 73 is p-doped. The doping concentration of the source region 73 can be in the same range as the doping concentration of the drain region 71.

The MOSFET can be implemented as an enhancement MOSFET or as a depletion MOSFET. In an enhancement MOSFET, the body region 74 is doped complementarily to the source region 73. In a depletion MOSFET, the body region 74 at least along the gate dielectric 76 includes a semiconductor region of the same doping type as the source region 73.

In the type of MOSFET illustrated in FIG. 16, the drift region 72 can have the same doping type as the drain region 71 and the source region 73, but could also be doped complementarily to the source region 73 and the drain region 71, wherein at least a section of the drift region 72 between the vertical dielectric structure 30 and the channel region of the MOSFET may have the same doping type as the source region 73. The “channel region” of the MOSFET is the region of the body region 74 along the gate dielectric 76.

Referring to FIG. 16, the gate electrode 75 is electrically connected to a gate terminal G (only schematically illustrated in FIG. 16) and the source and body regions 73, 74 are electrically connected to a source terminal S.

Referring to FIG. 16, the MOSFET further includes a drift control region 81 that is dielectrically insulated from the drift region 72 by the vertical dielectric structure 30. In this MOSFET, the vertical dielectric structure 30 acts as a drift control region dielectric. The drift control region 81 generates a conducting channel in the drift region 72 along the drift control region dielectric 30 when the MOSFET is in its on-state, so as to reduce the on-resistance of the MOSFET. The MOSFET, like a conventional MOSFET, is in its on-state, when an electrical potential is applied to the gate terminal G that causes a conducting channel in the body region 74 between the source region 73 and the drift region 72 along the gate dielectric 76, and when an electrical voltage is applied between the drain and the source terminals D, S. The conducting channel along the gate control region dielectric 30 is an accumulation channel when the drift region 72 has the same doping type as the source drain regions 73, 71, and is an inversion channel, when the drift region 72 is doped complementary.

The MOSFET further includes a biasing source 91 coupled to the drift control region 81. According to one embodiment (not illustrated) the biasing source 91 is implemented as a rectifier element, such as a diode, connected between the gate terminal G and the drift control region 81. Optionally, a capacitive storage element 93, such as a capacitor, is coupled between the drift control region 81 and a terminal for a reference potential, such as the source terminal S. Further, a rectifier element 92, such as a diode, is connected between the drain region 71 and the drift control region 81. Optionally, the rectifier element 92 is connected to a connection region 82 which has the same doping type as the drift control region 81, but a higher doping concentration. The connection region 82 may adjoin the first dielectric layer 12 and is already present in the semiconductor body that forms the basis for the method explained before.

Referring to FIG. 17, which illustrates a vertical cross sectional view of the drift control region 81 the rectifier element 92 can be connected to the drift control region 81 via the first surface 101. According to one embodiment, a further connection zone 84 of the same doping type as the connection zone 82 extends from the first surface 101 in a vertical direction to the connection zone 82. In the embodiment illustrated in FIG. 17, the drift control region 81 has an elongated (stripe-shaped geometry), where the rectifier element 92 is connected to the drift control region 81 at a longitudinal end. The vertical cross sectional view illustrated in FIG. 16 can be a cross sectional view in a section plane C-C illustrated in FIG. 17.

Referring to FIG. 16, the MOSFET may further include a semiconductor zone 83 doped complementarily to the drift control region 81. In this case, the biasing source 91 and the optional capacitive storage element 93 are connected to this semiconductor region 83.

The operating principle of the MOSFET is briefly explained next. For explanation purposes only it is assumed that the MOSFET is an n-type MOSFET with an n-doped drift zone 72, and that the drift control region 81 has the same doping type as the drift region 72. The biasing source 91 is configured to bias the drift control region 81 to a positive potential relative to the electrical potential of the source terminal S, when the MOSFET is in its on-state. The MOSFET is in its on-state, when the drive potential applied to the gate terminal G generates a conducting channel in the body region 74 between the source region 73 and the drift region 72, and when a positive voltage is applied between the drain and the source terminals D, S. In the on-state, the drift control region 81, which has a higher electrical potential than the drift region 72, generates an accumulation channel along the gate control region dielectric 30 in the drift region 72. This accumulation channel significantly reduces the on-resistance as compared to a MOSFET without drift control region 81. The MOSFET is in the off-state, when the channel in the body region 74 is interrupted. In this case, a depletion region expands in the drift region 72 beginning at the pn-junction between the body region 74 and the drift region 72. The depletion region 72 expanding in the drift region 72 causes a depletion region also to expand in the drift control region 81. By virtue of a depletion region expanding in the drift region 72 and a depletion region expanding in the drift control region 81, a voltage across the drift control region dielectric 30 is limited. The capacitive storage element 93 serves to store electrical charges that are required in the drift control region 81 when the MOSFET is in its on-state. The rectifier element 92 allows charge carriers that are thermally generated in the drift control region 81 to flow to the drift region 71.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

In addition, spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing a semiconductor device with a dielectric layer, the method comprising:
providing a semiconductor body with a first trench extending into the semiconductor body, the first trench having a bottom and a sidewall;
forming a first dielectric layer on the sidewall in a lower portion of the first trench;
forming a first plug in the lower portion of the first trench so as to cover the first dielectric layer, the first plug leaving an upper portion of the sidewall uncovered;
forming a sacrificial layer on the sidewall in the upper portion of the first trench;
forming a second plug in the upper portion of the first trench;
removing the sacrificial layer, so as to form a second trench having sidewalls and a bottom; and
forming a second dielectric layer in the second trench and extending to the first dielectric layer.

2. The method of claim 1, wherein forming the second dielectric layer comprises:
removing the first plug below the bottom of the second trench down to the second dielectric layer, so as to form a third trench; and
forming a third dielectric layer in the third trench, the third dielectric layer adjoining the second dielectric layer.

3. The method of claim 1, wherein forming the second dielectric layer comprises oxidizing the sidewalls of the second trench and the first plug below the second trench.

4. The method of claim 1, wherein the semiconductor body includes a first semiconductor layer, a second semiconductor layer, and a further dielectric layer arranged between the first semiconductor layer and the second semiconductor layer, with the further dielectric layer being uncovered at the sidewall of the first trench.

5. The method of claim 4, wherein the first dielectric layer is formed such that it covers the further dielectric layer on the sidewall of the first trench.

6. The method of claim 1, wherein forming the first dielectric layer comprises:
forming a dielectric layer covering the sidewall of the first trench; and
removing the dielectric layer in the upper portion of the first trench.

7. The method of claim 6, wherein removing the dielectric layer in the upper portion of the first trench comprises:
forming a mask layer on the bottom of the first trench; and
etching the dielectric layer using the mask layer as a mask.

8. The method of claim 7, wherein the mask layer is a semiconductor layer.

9. The method of claim 8, wherein the semiconductor layer is an epitaxial layer.

10. The method of claim 9, wherein forming the first plug comprises:
forming the mask layer to be a semiconductor layer; and
forming a further semiconductor layer on the mask layer.

11. The method of claim 10, wherein the further semiconductor layer is an epitaxial layer.

12. The method of claim 1, wherein the first plug is removed before the second plug is formed.

13. The method of claim 1, wherein forming the first and second plugs comprises epitaxially growing a semiconductor material.

14. The method of claim 1, wherein the sacrificial layer is an oxide layer.

15. The method of claim 1, wherein the second dielectric layer is an oxide layer.

16. The method of claim 1, further comprising forming a source region and a body region in the second plug.

17. A method for producing a semiconductor device with a dielectric layer, the method comprising:
providing a semiconductor body with a first trench extending from a first surface into the semiconductor body, the first trench having a bottom and a sidewall;
forming a protection layer on the sidewall;
forming a sacrificial layer on the sidewall, the sacrificial layer covering the protection layer;
forming a semiconductor plug in the first trench;
forming a second trench between the semiconductor body and the semiconductor plug, wherein forming the second trench at least comprises removing the sacrificial layer; and
forming a first dielectric layer in the second trench.

18. The method of claim 17,
wherein the semiconductor body comprises a first semiconductor layer, a second semiconductor layer, and a further dielectric layer arranged between the first semiconductor layer and the second semiconductor layer,
wherein the first trench extends through the second semiconductor layer and the further dielectric layer to the first semiconductor layer, and
wherein the first dielectric layer is uncovered at the sidewall of the first trench, and wherein the protection layer at least covers the first dielectric layer.

19. The method of claim 18, wherein forming the first dielectric layer in the second trench comprises oxidizing the second semiconductor layer, the protection layer and the semiconductor plug along sidewalls of the second trench.

20. The method of claim 17 wherein forming the first dielectric layer in the second trench comprises:
removing the protection layer; and
performing an oxidation step.

21. The method of claim 17, wherein the protection layer extends to the first surface of the semiconductor body.

22. The method of claim 17, wherein the protection layer leaves sections of the sidewall of the first trench uncovered.

23. The method of claim 18, wherein forming the protection layer and the sacrificial layer comprises:
forming a first layer on the sidewall of the first trench, the first layer at least covering the first dielectric layer and comprising a first sub-layer adjacent the first dielectric layer and a second sub-layer; and
oxidizing the second sub-layer leaving the first sub-layer non-oxidized, the first sub-layer forming the protection layer, the second sub-layer forming the sacrificial layer.

24. The method of claim 22, wherein forming the sacrificial layer further comprises oxidizing sections of the sidewalls that are uncovered by the first layer.

25. The method of claim 17, wherein the protection layer comprises at least one of an amorphous or polycrystalline semiconductor material.

26. The method of claim 17, wherein forming the second trench comprises:
removing the sacrificial layer so as to form a further trench;
forming a further sacrificial layer in the further trench; and
removing the further sacrificial layer, so as to form the second trench.

27. The method of claim 26, wherein forming the further sacrificial layer comprises an oxidation step.

28. The method of claim 27, wherein the oxidation step partially oxidizes the semiconductor plug and the protection layer.

29. The method of claim 18, wherein providing the semiconductor body with the trench comprises:
providing the semiconductor body with the first semiconductor layer, the second semiconductor layer, the first dielectric layer arranged between the first semiconductor layer and the second semiconductor layer, and the first trench extending from the first surface of the semiconductor body through the second semiconductor layer to the first dielectric layer;
etching the second semiconductor layer adjacent the first dielectric layer; and
further extending the first trench through the first dielectric layer.

30. The method of claim 17, further comprising forming a semiconductor layer on the sidewall of the first trench before forming the protection layer, the semiconductor layer leaving the first dielectric layer at least partially uncovered.

31. The method of claim 17, further comprising partially removing the sacrificial layer in the region of the first dielectric layer before forming the semiconductor plug.

32. The method of claim 17, further comprising forming the sacrificial layer such that the sacrificial layer partially covers the bottom of the first trench in sections adjoining the sidewall of the first trench.

33. The method of claim 17, wherein forming the semiconductor plug comprises an epitaxial growth of a semiconductor material on the bottom of the first trench.

34. The method of claim 17, further comprising forming a source region and a body region in the semiconductor plug.
